(19) United States
(12) Patent Application Publication
(10) Pub. No.: US 2011/0023927 A1
(43) Pub. Date: Feb. 3, 2011

(54) Micro-combustion power system with metal foam heat exchanger

(75) Inventors: Ying Hsu, San Clemente, CA (US); Itzhak Sapir, Irvine, CA (US); Medhat Azzazy, Laguna Niguel, CA (US)

Correspondence Address: W. ERIC BOYD, ESQ.;IRVINE SENSORS CORP., 3001 REDHILL AVENUE, BUILDING 4, SUITE 108, COSTA MESA, CA, 92626, US

(73) Assignees: Irvine Sensors Corporation, Costa Mesa, CA (US); Itzhak Sapir, Medhat Azzazy Ying Hsu

(21) Appl. No.: 12/800,746

(22) Filed: May 21, 2010

Related U.S. Application Data
(63) Continuation-in-part of application No. 11/482,208, filed on Jul. 7, 2006.
(60) Provisional application No. 60/697,298, filed on Jul. 8, 2005.
(60) Provisional application No. 60/698,903, filed on Jul. 14, 2005.

(51) Int. Cl. H01L 35/30

(52) U.S. Cl. 136/205

(57) ABSTRACT

A micro-combustion power system is disclosed. In a first embodiment, the invention is comprised of a housing that further comprises two flow path volumes, each having generally opposing flow path directions and each generally having opposing configurations.

Each flow path volume comprises a pre-heating volume having at least one pre-heating heat exchange structure. Each flow path volume further comprises a combustion volume having a combustion means or structure such as a catalytic material disposed therein Further, each flow path volume comprise a post-combustion volume having at least one post-combustion heat exchange structure.

One or more thermoelectric generator means is in thermal communication with at least one of the combustion volumes whereby thermal energy generated by an air/fuel catalytic reaction in the combustion volume is transferred to the thermoelectric generator to convert same to electrical energy for use by an external circuit.

In a second embodiment, a micro-combustion power system device is disclosed comprising a housing defining a flow path volume wherein the flow path volume comprises a pre-heating volume having a pre-heating heat exchange structure disposed therein. The embodiment further comprises a combustion volume with combustion means and a post-combustion volume having a post-combustion heat exchange structure disposed therein. Further, the embodiment comprises a thermoelectric generator means with its first surface in thermal communication with the combustion volume and its second surface in thermal communication with heat radiator means such as a reticulated metal foam heat exchange structure.

### CROSS-REFERENCE TO RELATED APPLICATIONS

This application claims the benefit of U.S. Provisional Patent Application No. 61/268,660, filed on Jun. 15, 2009 entitled “Micro-fueled Power Source Comprising Metal Foam Heat Exchanger” pursuant to 35 USC 119, which application is incorporated fully herein by reference.

This application is a continuation-in-part of and claims the benefit of U.S. patent application Ser. No. 12/584,460, filed on Sep. 4, 2009 entitled “Micro-combustion Power System with Dual Counter Flow System” which in turn claims priority to U.S. Provisional Application No. 61/191,533 filed Sep. 9, 2008 pursuant to 35 USC 119, which applications are incorporated fully herein by reference.

This application is a continuation-in-part of and claims the benefit of U.S. patent application Ser. No. 11/482,208, filed on Jul. 7, 2006 entitled “Energy Efficient Micro-combustion System for Power Generation and Fuel Processing” which in turn claims priority to U.S. Provisional Application No. 60/697,298 filed Jul. 8, 2005 and U.S. Provisional Application No. 60/698,903 filed Jul. 14, 2005 pursuant to 35 USC 119, which applications are incorporated fully herein by reference.

### STATEMENT REGARDING FEDERALLY SPONSORED RESEARCH AND DEVELOPMENT

This invention was made with Government support under Contract No. FA-8651-06-M-0180 awarded by the United States Air Force.

The Government has certain rights in the invention.

### DESCRIPTION

1. Field of the Invention

The invention relates generally to the field of micro-combustion electrical power systems. More specifically, the invention relates to MEMS-scale electrical power systems that utilize a combustible fuel to produce electrical power using a thermoelectric generator element.

2. Background of the Invention

Mobile electronic devices are common in consumer, industrial and military environments. Due to their portable nature, mobile electronic devices typically rely on a portable electrical power source such as one or more batteries.

A new form of portable electrical power source has been developed out of several technological breakthroughs, namely developments in micro-scale combustion (micro-combustion) and high-efficiency thermoelectric materials.

The advent of these two technologies enables electrical power generation using the high energy content of liquid hydrocarbon fuels such as propane, butane, kerosene, JP-8 or gasoline in such small form factors as to be compatible with mobile applications. Liquid hydrocarbon fuels have a very high energy density; in the range of 70 to 100 times that of the current lithium-ion based batteries. Given this high energy content, even a modest energy conversion efficiency of 10% results in potentially a ten times improvement in current battery energy density.

Thermal and liquid reserve batteries generally separate the electrolyte from active electrodes and maintain the electrolyte in solid state until activation. Micro-combustion power systems have similar design advantages in that the fuel is physically separated from the energy converter chips. Until the fuel is channeled into the microcombustor and activated, no electro-chemical action takes place, thereby enhancing the reliability of the system.

What is currently lacking is a mobile electrical power system that combines the above technologies to accomplish reliable, miniature power generation with features such as a MEMS-based micro-combustion power system with multiple cells capable of reliably providing sustained power levels of one to 50 or more watts. This relatively high power is, for instance, an enabling technology for use in miniaturized smart munitions or to achieve greater autonomy and improved flight control in military systems.

Further needed is a micro-combustion power system that has a capacity in the range of 10 to 200 or more watts-hours. In this range, a micro-combustion power system exceeds the performance of electrochemistry batteries or fuel cells with a potential advantage of in the range of eight times higher energy density than existing lithium-ion.

The above invention is desirably implemented as a MEMS-based micro-combustion power system comprising micro-machined silicon structures that are small and lightweight and can be easily packaged to protect the device from harsh operating environments.

### SUMMARY OF THE INVENTION

The instant invention takes advantage of MEMS-scale technology and the catalytic combustion reaction arising out of the oxidation of a combustible fuel such as a hydrocarbon interacting with a catalytic material.

In a preferred embodiment, the invention is comprised of a housing that further comprises two flow path volumes, each having generally linear and opposing flow path directions and each generally having opposing configurations.

Each flow path volume comprises a pre-heating volume having at least one pre-heating heat exchange structure. Each flow path volume further comprises a combustion volume having a combustion means or structure such as a catalytic material disposed therein. Further, each flow path volume comprises a post-combustion volume having at least one post-combustion heat exchange structure.

One or more thermoelectric generator means is in thermal communication with at least one of the combustion volumes whereby thermal energy generated by the catalytic reaction in the combustion volume is transferred to the thermoelectric generator to convert same to electrical energy for use by an external circuit.

In operation, a predetermined amount of fuel is combined in an air/fuel mixture and is introduced into each respective pre-heating volume by a fuel valving means and by air pressurization means (such as a fan). The air/fuel mixture is directed from the pre-heating volume into the combustion volume where the oxidation reaction of the air/fuel mixture in the presence of the catalytic material generates thermal energy.

The resultant thermal energy is transferred to the thermoelectric generator means which converts same into electrical energy.

The heated exhaust gases from the catalytic reaction are then directed further into the respective post-combustion volumes whereby entrained thermal energy in the exhaust gas is absorbed by the post-combustion heat exchange structures disposed therein.

In one preferred embodiment, a micro-combustion power system device is disclosed comprising a housing defining at least one generally linear flow path volume wherein the flow path volume comprises a pre-heating volume having a pre-heating heat exchange structure disposed therein. The embodiment further comprises a combustion volume with combustion means and a post-combustion volume having a post-combustion heat exchange structure disposed therein.

Further, the embodiment comprises a thermoelectric generator means with its first surface in thermal communication with the combustion volume and its second surface in thermal communication with heat radiator means such as metal foam heat exchange structure using a heat pipe structure.

A novel element of the invention in the first discussed embodiment relates to the opposing configuration and opposing linear flow path directions of the respective flow path volumes. In this embodiment, the pre-heating heat exchange structure in the first flow path volume and the opposing post-combustion heat exchange structure are comprised of a shared, thermally conductive structure and material. In this embodiment, waste heat from the exhaust gas in the post-combustion chamber is transferred to the opposing pre-heating volume to heat the air/fuel mixture therein to a suitable pre-combustion temperature to take advantage of waste heat while better managing thermal/cooling issues of the device during operation.

A novel element of the invention in a second preferred embodiment relates to the use of a separately provided heat management assembly comprising one or more heat sinks, one or more heat pipes and one or more heat radiator means such as a reticulated metal foam heat exchanger.

### BRIEF DESCRIPTION OF THE DRAWINGS

FIGS. 1a and 1b are cross-sectional views of a preferred embodiment of the invention.

FIG. 2 is a perspective view of FIGS. 1a and 1b of a preferred embodiment invention.

FIG. 3 is a cross-section showing another view of a preferred embodiment of the invention.

FIG. 4 shows perspective view of a preferred embodiment of the invention comprising heat pipe and heat radiator means for removal of heat from the thermoelectric generator element.

FIG. 5 is a cross-section of a preferred embodiment of the invention comprising heat pipe and heat radiator means for removal of heat from the thermoelectric generator element.

FIG. 6 is an exploded view of the invention illustrated in FIGS. 4 and 5.

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

### DETAILED DESCRIPTION OF THE INVENTION

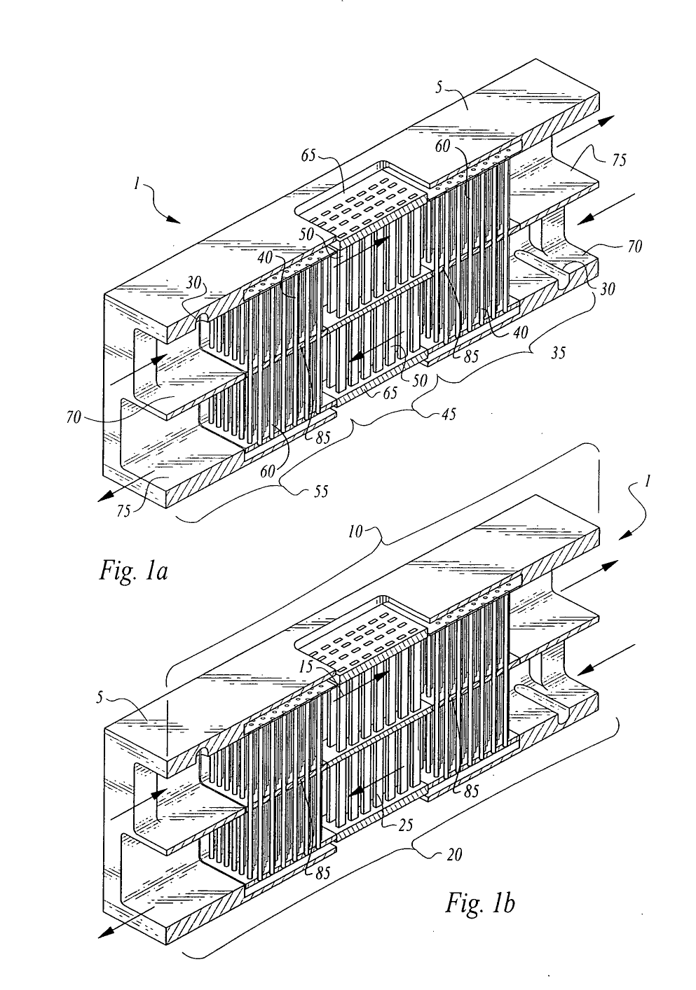

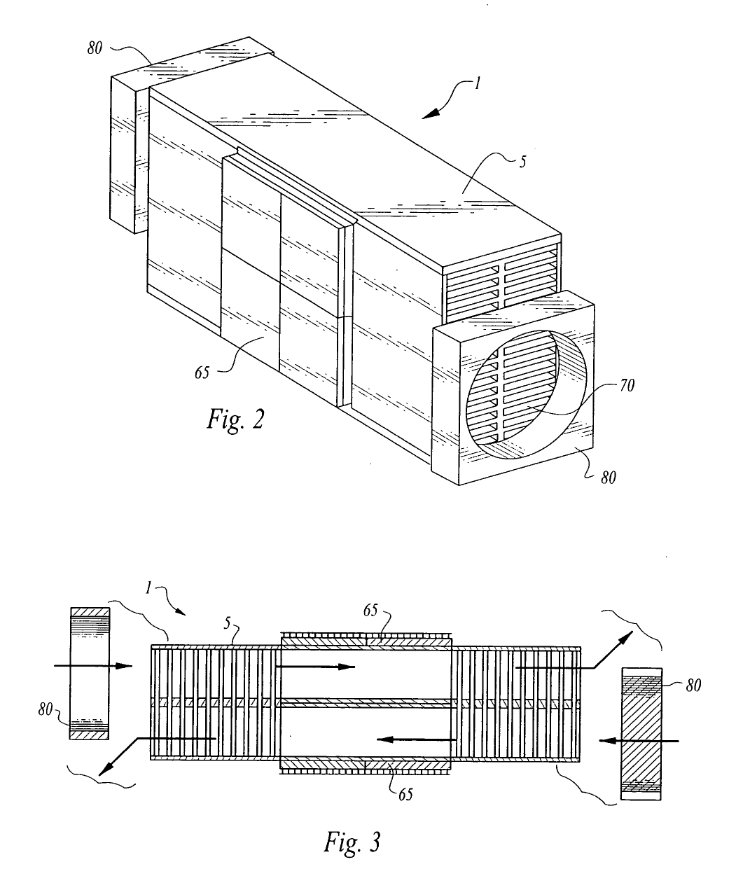

Turning now to the figures wherein like numerals define like elements among the several views, FIGS. 1a, 1b, 2 and 3 illustrate a preferred embodiment of the dual path counter-flow micro-combustion power system 1 of the invention.

As seen in FIGS. 1a and 1b, micro-combustion power system 1 comprises a housing 5. Housing 5 comprises a generally linear first flow path volume 10 having a first flow path direction 15 and a generally linear second flow path volume 20 having a second flow path direction 25 opposing the first flow path direction 15.

Each of the flow path volumes comprise fuel valving means 30, a pre-heating volume, 35, a pre-heating heat exchange structure 40, a combustion volume 45, combustion means 50, illustrated as a generally planar, finned element herein, a post-combustion volume 55, a post-combustion heat exchange structure 60, at least one thermoelectric generator means 65, an inlet port 70, an outlet port 75, air pressurization means 80 and insulating heat exchange frame means 85.

In a preferred embodiment, micro-combustion power system 1 is fabricated using micro-machined electro-mechanical systems processes (i.e. MEMS) to provide a very small form factor, high electrical power-to-weight power source.

The fuel utilized in the combustion process may be any fuel with suitable thermal and combustion properties for the generation of heat to generate electric power from the selected thermoelectric generator means as is further discussed below. Exemplar fuel means may comprise, by way of example and not by limitation, gasoline, propane, hydrogen, kerosene, JP-8, butane or other equivalent fuels or liquid hydrocarbons.

Fuel valving means 30 introduces a predetermined amount of fuel into pre-heating volume 35. Mixing air is also supplied to pre-heating volume 35 through inlet port 70 at a predetermined fuel/air ratio for subsequent combustion. Mixing air is preferably introduced into pre-heating volume 35 by air pressurization means 80.

Air pressurization means 80 may, by way of example, comprise a synthetic MEMS or piezoelectric air jet actuator, fan, compressed air source or equivalent. Suitable control electronics are provided to support the appropriate elements of the invention, for instance, for the control of air pressurization means 80 and fuel valving means 30.

Fuel valving means 30 may be selected by its ability to suitably atomize and/or vaporize the selected fuel. By way of example and not by limitation, fuel valving means 30 may comprise an orifice, port or aperture of a predetermined geometry disposed at an appropriate location with respect to pre-heating volume 35, a micro-scale shutoff valve, a nozzle or micro-nozzle such as are used in inkjet printing, a fuel injector or a capillary force vaporizer as is available from Vapore, Inc.

In a preferred embodiment, fuel is introduced into the microcombustion system using the fuel valving means 30 of each of the first flow path volume 10 and second flow path volume 20. Fuel valving means 30 is disposed proximal the respective inlet port 70 of each flow path volume to provide a predetermined air/fuel mixture ratio. Air pressurization means 80 is utilized to direct the air/fuel mixture toward and through pre-heating volume 35 and across the surface of the one or more pre-heating heat exchange structures 40. As is discussed further below, in this configuration, a portion of the thermal energy contained within the pre-heating heat exchange structures 40 is beneficially transferred into the air/fuel mixture as it passes over the surface thereof.

Combustion volume 45 is provided in fluid communication with pre-heating volume 35 for the receiving of the pre-heated air/fuel mixture. Combustion volume 45 is comprised of combustion means 50 which may, by way of example and not by limitation, comprise a plated-on catalytic material such as platinum, palladium or other equivalent catalytic combustion means.

Combustion means 50 may be plated or disposed on the interior surface of combustion volume 45 or plated or disposed upon a high-surface area structure such as the illustrated generally planar, finned combustion means element 50 which maximizes the surface area available for a catalytic reaction between the air/fuel mixture and combustion means 50.

Ignition means such as a spark element, micro-flame or equivalent may optionally be provided in or proximate combustion volume 45 to initiate a combustion reaction.

The combustion reaction that occurs within combustion volume 45 between the air/fuel mixture and combustion means 50 generates thermal energy and heated exhaust gas as a byproduct.

As seen in FIGS. 1a, 1b, and 5, combustion means 50 is in thermal communication with at least one thermoelectric generating means 65.

Thermal energy from the earlier referenced combustion reaction is transferred to the warm side of thermoelectric generating means 65 that is proximate and in thermal communication with at least a portion of combustion volume 45.

Preferred embodiments of thermoelectric generator means 65 include bismuth telluride and lead telluride, thin film such as super-lattice or quantum well devices or nano-composite structures or any equivalent thermoelectric generator devices capable of generating electrical power using thermal energy as an input.

Because lead telluride and bismuth telluride have significantly different thermoelectric performance characteristics across the expected operating temperature range of the invention, a two-stage design using both materials can be used to improve device efficiency and to reduce maximum operating temperature.

FIGS. 1a and 1b reflect a preferred embodiment of combustion means 50 showing a generally planar, finned element that has its channeled surface area plated with a catalytic material to define combustion means 50. A finned combustion means element 50 is desirably disposed within the interior of combustion volume 45 to generate a combustion reaction. The channel surfaces of finned combustion means element 50 are, for instance, coated with a suitable catalyst, typically platinum or palladium such as is available from Catacel Corp. (Garrettsville, Ohio).

Substrate materials for finned combustion means element may comprise, for instance, silicon, ceramic or stainless steel.

As further seen in FIGS. 1a, 1b, and 3, heated exhaust gases from the combustion reaction in combustion volume 45 are transferred into post-combustion volume 55. Post-combustion volume 55 comprises post-combustion heat exchange structure 60 for the absorbing and transfer of thermal energy entrained in the heated exhaust gas. In this manner, thermal energy entrained within the exhaust gases from combustion is transferred, in part, to post-combustion heat exchange structure 60 which is disposed within or proximate post-combustion volume 55.

As noted above, a novel feature of this embodiment of the invention relates to the opposing configuration and opposing generally linear flow path directions of the respective flow path volumes. In this embodiment, pre-heating heat exchange structure 40 in first flow path volume 10 and the complementary post-combustion heat exchange structure 60 disposed in post-combustion volume 55 are comprised of a shared, thermally conductive structure and material, for instance a copper material (e.g., copper pins) or other suitable equivalent thermal structure.

Each of the respective heat exchange structures is preferably disposed in a thermally insulative frame means 85. Insulative frame means 85 is preferably comprised of a material that permits thermal energy transfer vertically along and through the heat exchange structures (e.g., heat conducting structures) while limiting heat transfer in other directions between the respective pre-heating and post-combustion volumes and limiting heat transfer along the flow path volumes themselves.

Insulative frame means 85 is desirably fabricated from a thermally insulative material such as Vespel SP1 as is available from DuPont E. I. De Nemours & Co.

In this manner, the heat exchange structures provide a well-defined and uniform thermal path through and into the pre-heating and post-combustion volumes while insulative frame means 85 minimizes flow path stream heat conduction along the interior walls of the flow path volumes. This in turn, beneficially minimizes the temperature difference across the heat exchange structures for higher system efficiency.

The same shared heat exchange configuration is seen in FIGS. 1a, 1b and 3 where the pre-heating heat exchange structure 40 disposed within second flow path volume 20 is a commonly shared, thermally conductive material and element that is shared with the post-combustion heat exchange structures 60 disposed within first flow path volume 15.

In other words, each of the respective pre-combustion heat exchange structures and post combustion heat exchange structures in the adjacent first and second flow paths function as heat paths for the transfer of post-combustion thermal energy into the adjacent pre-heating volumes. In this embodiment, waste heat from the exhaust gas in the post-combustion chamber is thermally transferred to the opposing pre-heating volume to heat the air/fuel mixture therein to a suitable pre-combustion temperature to take advantage of waste heat while better managing thermal/cooling issues of the device during operation.

The exhaust gases in post-combustion volume 55 pass through outlet port 75 to an external location.

The invention preferably uses simple liquid hydrocarbon fuels that are widely available, that can be easily stored and are in gaseous form at normal operating temperature range. Examples of these fuel types include butane and propane which are used in consumer products such as cigarette lighters and portable cooking stoves.

For military applications however, one of the most commonly used fuels is jet fuel such as JP-8. The makeup of JP-8 is essentially kerosene mixed with other hydrocarbons and additives that allow the fuel to combust over a wide range of temperatures and conditions.

For the invention to efficiently operate using JP-8, the selected fuel valving means 30 should be able to handle the fuel in liquid form at ambient conditions. To combust optimally, the liquid JP-8 fuel is ideally atomized into droplets, vaporized, and mixed with the oxidant (air). Injecting JP-8 through a micro-nozzle (similar to ink jet technology) to generate small droplets is one preferred embodiment of the invention.

Generation of fuel vapor for combustion using a thermally-driven injector (capillary force vaporizer or CFV injector) may also be accomplished by use of a combination of capillary and vaporization forces. This approach simplifies the operation and manufacture of the invention.

Using a CFV injector embodiment provides a number of benefits. For example, a CFV injector uses heat as the driver to produce pressurized fuel vapor. The invention can desirably use excess exhaust heat as an energy source for the injector. A CFV injector is also capable of working with complex fuels such as JP-8 and is readily available.

Prior art microcombustion power supply devices have an undesirable attribute in that the air/fuel flow pressure drop through the heat exchanger and combustion components is relatively high due to the long flow path length necessary to achieve efficient convective heat transfer. A beneficial result of the shared heat exchange structure elements of the instant invention is enhanced thermal management of the device and a significant reduction in the flow path length of the system with a related low pressure drop through the system.

The disclosed embodiment of the invention overcomes the above deficiencies in prior art micro-combustion power supply devices by providing a dual path, counter-flow system. By dividing the microcombustor device into two or more sections, the invention is able to recover and recycle exhaust heat by disposing the post-combustion heat exchange structure downstream of each combustion volume to pre-heat the incoming cold air/fuel mixture stream. The resultant benefit is an air/fuel mixture flow arrangement with two direct and opposing flow paths and minimum pressure drop along each of the paths.

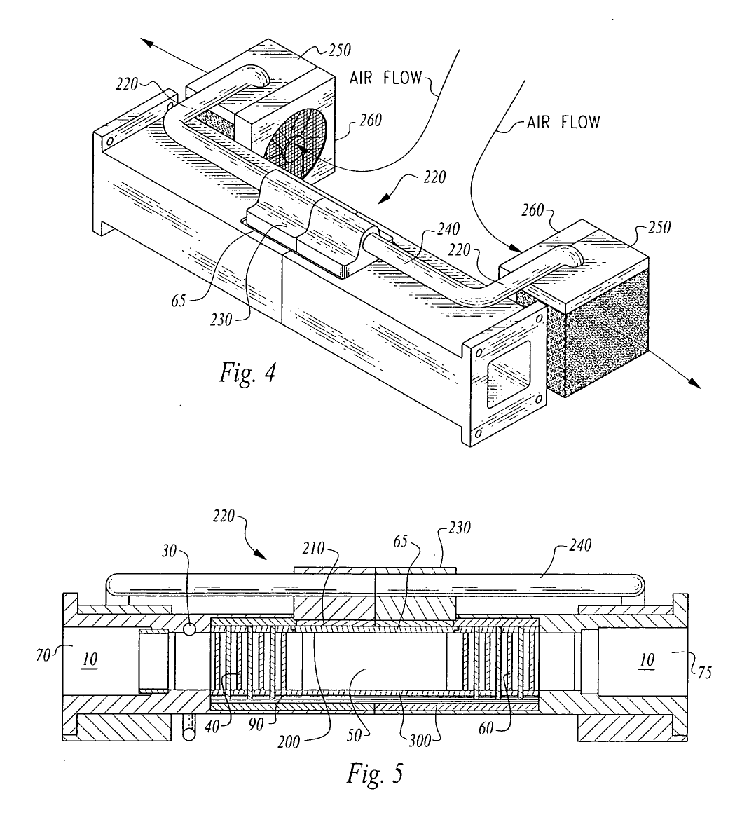

Yet a further alternative preferred embodiment of the microcombustion power system of the invention is illustrated in FIGS. 4, 5 and 6.

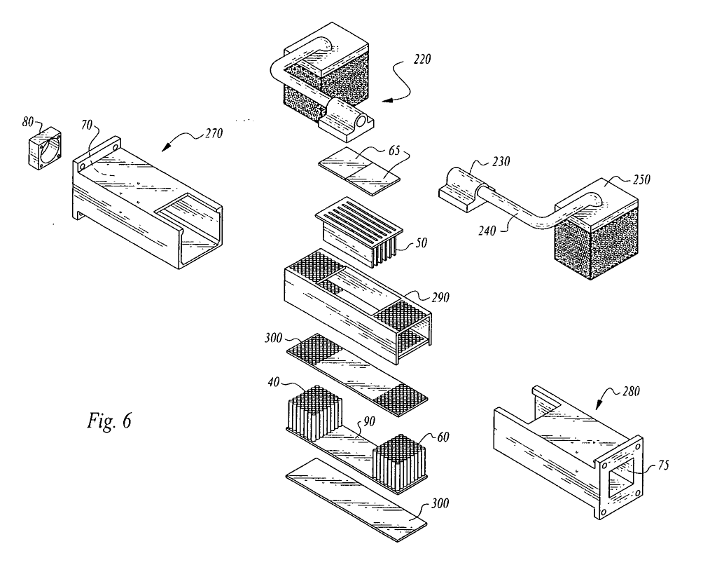

In this embodiment and as best seen in FIG. 6, combustion means 50 is disposed about in the center of the illustrated flow path with two heat exchange elements (i.e., a pre-heating exchange structure 40 and a post-combustion heat exchange structure 60 in thermal communication with each other, for instance, by means of thermally conductive base 90). Each heat exchange element is respectively disposed upstream and downstream from combustion volume 45 and combustion means 50 for heat recovery and transfer of heat from post-combustion heat exchange structure 60 to pre-combustion heat exchange structure 40. In this embodiment, a pair of thermoelectric generator means 65 are disposed above the combustion volume 45 and in thermal communication therewith. In this embodiment, a single low power fan provides air and air pressurization means 80 for combustion and the fuel is introduced to through the inlet port using a small conduit connected to an external fuel cartridge.

In this embodiment, at least one flow path volume 10 is provided. This embodiment comprises at least one thermoelectric generating means 65 comprising a first surface 200 and a second surface 210 in thermal communication with heat transfer means 220, here shown as one or more heat sink structures 230 in thermal communication with one or more heat pipe structures 240.

Heat sink structure 230 may be comprised of any material having suitable thermal conductivity properties such as a copper heat sink.

Heat pipe structure 240 may, in a preferred embodiment, comprise a sealed conduit having a hot and a cold end under a partial vacuum and filled with a working fluid of a suitable match to the system's operating temperature wherein a portion of the fluid is in a liquid phase and a portion of the fluid is in the gas phase during heat transfer operation. The interior of the conduit may comprise a series of grooves parallel to the conduit axis. The heat pipe structure 240 comprises a sealed conduit structure with an interior surface comprising a capillary wicking material. A heat pipe has the ability to transport heat against gravity by an evaporation-condensation cycle with the help of porous capillaries that form the wick and provides a capillary driving force to return the condensate to the evaporator. It is expressly noted that any suitable thermally conductive structure may be used and that the invention is not limited to the use of a heat pipe structure for the transfer of heat from the thermoelectric generating element.

Heat transfer means 220 is configured to provide a thermal path between second surface 210 of thermoelectric generator means 65 to one or more heat radiation means such as one or more reticulated metal foam heat exchange structures 250 as illustrated in FIG. 4.

By way of example and not by limitation, metal foam heat exchange structure 250 may be comprised of reticulated, open cell metal foam (RMF) material as is available from ERG Materials and Aerospace Corporation or Porvair Fuel Cell Technology Inc., comprising randomly oriented, polygon-shaped, thermally conductive cell structures. In a preferred reticulated metal foam heat exchange embodiment, a metal foam of 85% porosity is capable of rejecting about 85 watts using an air flow of about 60 liters/minute with an associated pressure drop at about 140 Pa.

Because thermoelectric generator means 65 generates electrical power as the result of a temperature differential between first surface 200 and second surface 210, heat from second surface 210 is beneficially drawn away from thermoelectric generator means 65 via heat transfer assembly 220 to the one or more metal foam heat exchange structures 250 for exhausting heat to a predetermined location such as by fans 260.

Again turning to FIG. 6, a first housing portion 270, a second housing portion 280 and an inner housing portion 290 are provided. Thermally insulative layers 300 are preferably provided and disposed so as to thermally isolate pre-combustion heat exchange structure 40, thermally conductive base 300 and post-combustion heat exchange structure 60.

In this manner, a suitable temperature differential is maintained between first surface 200 and second surface 210 in order that electrical power is generated.

It is expressly noted that a plurality of the above micro-combustion power systems can be configured in series or parallel to provide greater voltage, current or power output than an individual micro-combustion cell provides.

Many alterations and modifications may be made by those having ordinary skill in the art without departing from the spirit and scope of the microcombustion power system invention disclosed herein. Therefore, it must be understood that the illustrated embodiments have been set forth only for the purposes of example and that it should not be taken as limiting the invention as defined by the following claims. For example, notwithstanding the fact that the elements of a claim are set forth below in a certain combination, it must be expressly understood that the invention includes other combinations of fewer, more or different elements, which are disclosed above even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements. The claims are thus to be understood to include what is specifically illustrated and described above, what is conceptually equivalent, what can be obviously substituted and also what essentially incorporates the essential idea of the invention.

We claim:

1. A micro-combustion power system device comprising:
a housing defining a flow path volume,
said flow path volume comprising a pre-heating volume having a pre-heating heat exchange structure disposed therein,
a combustion volume comprising combustion means,
a post-combustion volume having a post-combustion heat exchange structure disposed therein,
a thermoelectric generator means having a first surface and a second surface,
said first surface in thermal communication with said combustion volume and said second surface in thermal communication with a heat pipe structure and a heat radiation means.

2. The micro-combustion power system device of claim 1 wherein said heat radiation means is comprised of a reticulated metal foam structure.

3. The micro-combustion power system device of claim 1 further comprising a fuel and air pressurization means for directing an air/fuel mixture through said flow path volume.

4. The device of claim 2 wherein said thermoelectric generator means in is thermal communication with said reticulated metal foam heat exchange structure by means of a heat pipe structure.

5. The device of claim 3 wherein said air/fuel mixture is comprised of a liquid hydrocarbon.

6. The device of claim 3 wherein said fuel is selected from the group consisting of JP-8, gasoline, kerosene, butane, hydrogen and propane.

7. The device of claim 3 wherein said fuel valving means is comprised of a capillary force vaporizer.

8. The device of claim 3 wherein said fuel valving means is comprised of an orifice having a predetermined geometry.

9. The device of claim 3 wherein said fuel valving means is comprised of a fuel injector.

10. The device of claim 3 wherein said fuel valving means is comprised of a micro-shut off valve.

11. The device of claim 3 wherein said fuel valving means is comprised of a micro-nozzle.

12. The device of claim 3 wherein said combustion means is comprised of a platinum material.

13. The device of claim 3 wherein said thermoelectric generating means is comprised of a lead telluride material.

14. The device of claim 3 wherein said thermoelectric generating means is comprised of a bismuth telluride material.

15. The device of claim 3 wherein said thermoelectric generating means is comprised of a lead telluride material and a bismuth telluride material.

16. The device of claim 3 wherein said pre-heating heat exchange structure and said post-combustion heat exchanger structure are in thermal communication whereby heat from said post-combustion heat exchange structure is transferred to said pre-heating heat exchange structure.

17. The device of claim 3 further comprising a thermally insulative frame structure.
